(19) United States
(12) Patent Application Publication
(10) Pub. No.: US 2026/0353893 A1
(43) Pub. Date: Nov. 5, 2026

(54) HIGH VOLTAGE LED EMITTER

(71) Applicant: Lumileds LLC, SanJose, CA (US)

(72) Inventors: Ronald Johannes Bonne, Plainfield, IL (US); Erik William Young, San Jose, CA (US); Florent Gregoire Monestier, Kerkrade (NL); Antonio Lopez Julia, Eindhoven (NL)

(21) Appl. No.: 19/487,992

(22) PCT Filed: May 17, 2024
(86) PCT No.: PCT/US2024/029987

§ 371 Date: Nov. 25, 2025

Related U.S. Application Data
(60) Provisional application No. 63/469,981, filed on May 31, 2023.

(51) Int. Cl. H10H 29/80; B60Q 1/04; H10H 29/01

(52) U.S. Cl. CPC H10H 29/8421; B60Q 1/04; H10H 29/032; H10H 29/034; H10H 29/8321

(57) ABSTRACT

A high-power LED array driven at greater than about 6V for vehicular applications and methods of fabricating the LED array are described. A mirror is disposed on n-and p-semiconductor layers. A dielectric spacer is disposed between the p-semiconductor and the mirror. A hard mask is deposited on the dielectric spacer and has openings with a conductor to the mirror. Dielectric layers are deposited on the hard mask. Bonding layers formed on the dielectric layers connect to the semiconductors. Trenches extend through the semiconductors to form series-connected pixels. A dielectric spacer layer stack is disposed on the sidewalls of the trenches to form a Bragg reflector. A redistribution dielectric (RDL) layer is disposed on the bonding layers. Under Bump Metallurgy (UBM) pads deposited on the RDL layer are coupled to a bonding layer of the first pixel and the last pixel via the openings in the RDL layer.

### PRIORITY CLAIM

This application claims the benefit of priority to U.S. Provisional Patent Application Ser. No. 63/469,981, filed May 31, 2023, which is incorporated herein by reference in its entirety.

### FIELD OF THE DISCLOSURE

The present disclosure relates to light emitting diode (LED) arrays. In particular, embodiments are directed to driving LED arrays.

### BACKGROUND OF THE DISCLOSURE

Driver architectures for LED arrays may enable the LEDs to be relatively efficient at the cost of being monetarily expensive. In certain environments, however, increasing the efficiency is less desirable than a significant cost reduction.

### BRIEF DESCRIPTION OF THE DRAWINGS

FIG. 1 shows an example of a driver architecture.

FIG. 2 illustrates an LED array, in accordance with some examples.

FIG. 3 illustrates isolated pixels, in accordance with some examples.

FIG. 4A illustrates a cross-section of an LED array during fabrication, in accordance with some examples.

FIG. 4B illustrates another cross-section of the LED array during fabrication after FIG. 4A, in accordance with some examples.

FIG. 4C illustrates another cross-section of the LED array during fabrication after FIG. 4B, in accordance with some examples.

FIG. 4D illustrates another cross-section of the LED array during fabrication after FIG. 4C, in accordance with some examples.

FIG. 5A illustrates a top view of a high voltage LED array during fabrication, in accordance with some examples.

FIG. 5B illustrates a top view of the high voltage LED array during fabrication after FIG. 5A, in accordance with some examples.

FIG. 5C illustrates a top view of the high voltage LED array during fabrication after FIG. 5B, in accordance with some examples.

FIG. 5D illustrates a top view of the high voltage LED array during fabrication after FIG. 5C, in accordance with some examples.

FIG. 5E illustrates a top view of the high voltage LED array during fabrication after FIG. 5D, in accordance with some examples.

FIG. 5F illustrates a top view of the high voltage LED array during fabrication after FIG. 5E, in accordance with some examples.

FIG. 5G illustrates a top view of the high voltage LED array during fabrication after FIG. 5F, in accordance with some examples.

FIG. 6 illustrates an example of a general device in accordance with some embodiments.

FIG. 7 illustrates an example lighting system, according to some embodiments.

FIG. 8 illustrates an example hardware arrangement for implementing the above disclosed subject matter, according to some embodiments.

FIG. 9 illustrates an example method of fabricating an illumination device, according to some embodiments.

FIG. 10 illustrates another driver architecture, in accordance with some examples.

FIG. 11 is a diagram of an example vehicle headlamp system.

### DETAILED DESCRIPTION

Existing LED driver architectures contain a variety of components, some of which are excessively expensive for the system in which the driver and LED array is to be located. In some systems, notably (but not only) vehicular systems, cost is one of the parameters used to determine attractiveness of a particular LED system for a particular application.

LED arrays may be used for many applications, including, for example, both interior and exterior automotive lighting. In particular, the use of LED arrays in automotive headlamps is gaining attraction as it allows selective illumination of an entire roadway or of only selected sections of the roadway, the latter of which is able to be used to reduce problems associated with glare or dazzling of oncoming drivers if combined with the individual driving. In this case, infrared cameras in the headlamp or elsewhere in the vehicle may be used as sensors, the LED arrays activate only those pixels used to illuminate the roadway, while deactivating pixels that may dazzle pedestrians or drivers of oncoming vehicles. In addition, off-road pedestrians, animals, or signs, for example, may be selectively illuminated to improve driver environmental awareness. For pixels of the LED array that are spectrally distinct, the color temperature of the light may be adjusted according to, for example, ambient lighting conditions such as daylight, twilight, or night conditions.

Such adaptive driving beam (ADB) systems may be formed from individual light emitting sources having an area of a few square millimeters (miniLEDs) down to a few square micrometers (microLEDs) depending on the matrix or display size and pixel-per-inch requirements of the matrix or display size. Each LED may be coupled with primary optics such as an array of collimators and secondary optics. Other common applications supported by LED arrays include video lighting, architectural and area illumination, street lighting, and informational displays.

One consideration related to ADB systems that use high-power LED arrays is the cost of electronics used to control each pixel. Matrix drivers (also called matrix controllers), which are used to individually control each LED of the array, are relatively expensive. For example, the cost of matrix drivers for a M×N LED array costs more than ⅓ of the total price of the ADB light source.

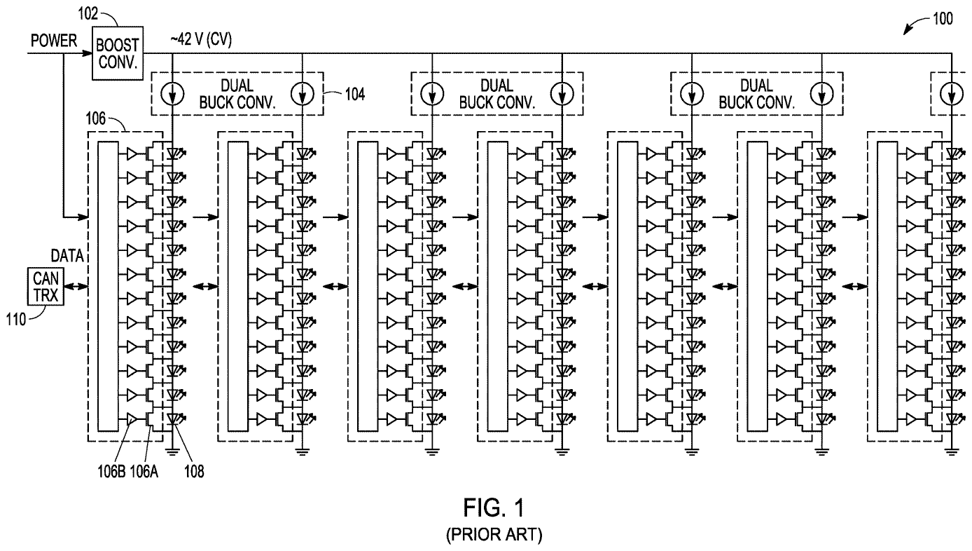

FIG. 1 shows an example of a driver architecture. The driver architecture 100 may be disposed in a vehicle or used in other consumer or industrial applications. The driver architecture 100 may be an M×N driver architecture that includes multiple matrix drivers 106. Each of the matrix drivers 106 has twelve bypass switches 106a integrated to control a string of twelve LEDs 108. Multiple strings of LEDs 108 are connected in parallel to create an M×N LED architecture (FIG. 1 shows an 84-up system (7*12) as an example). Each bypass switch 106a is connected to a level shifter 106b to set an appropriate voltage for the bypass switch 106a as the bypass switches 106a are not grounded. Each of the string of LEDs 108 uses a constant current source, typically in the form of a switched mode down converter (buck converter 104). Power from a battery may be supplied to a boost converter 102 that increases the battery voltage of typically 8-12V to about 42V to provide a constant array voltage, which is then converted to a relatively high constant current of about 700 mA by the buck converter 104. As shown, a single buck converter 104 may provide separate constant currents to two strings of LEDs 108. LED matrix drivers are monolithic high-efficiency LED drivers designed to supply LED arrays used in the backlighting of LCD panels various applications. Note that the term “about x” and similar terms (e.g., substantially) as used herein may be understood to be within 10% of x or otherwise within a range known to one of skill in the art to be within tolerance of the quantity or quality described unless indicated otherwise.

A digital serial interface connected to a vehicle Controller Area Network (CAN) bus 110 may be provided for control of each LED in the strings of LEDs 108. The LEDs of a string of LEDs 108 are coupled in series, with the associated bypass switch 106a of an LED acting as a shunt to allow the LED to be bypassed. This permits individual control of the operation of tightly packed (e.g., 80-100) high-power LEDs.

As above, such a driver architecture 100 may be relatively expensive as not only is a boost converter and CAN interface used to operate the LEDs, but a large number of matrix drivers and associated buck converters are used. To reduce the cost of an ADB headlamp system that contains one or more high-power LED arrays, simpler (linear) drivers may be used, in addition to high voltage LEDs that are compatible with the linear drivers. High voltage LEDs may include segmentation of active regions of the array and serially connecting the segmented active regions.

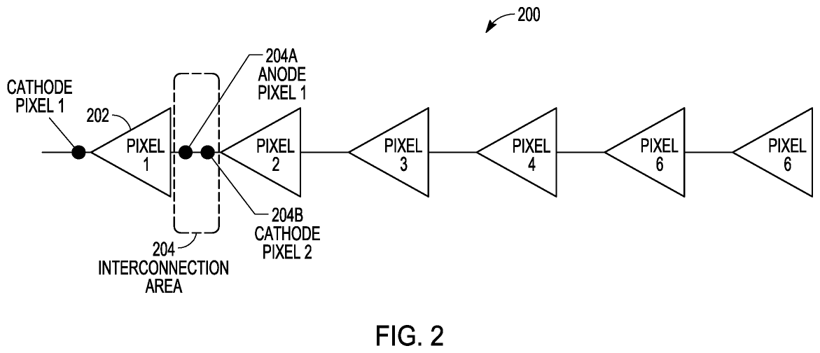

FIG. 2 illustrates an LED array, in accordance with some examples. As shown in the LED array 200 in FIG. 2, serial interconnection (e.g., serial intercoupling) is established by coupling the anode 204a of one pixel 202 to the cathode 204b of the following pixel 202 (or the cathode 204b of the pixel 202 to the anode 204a of the following pixel 202) in an interconnection area 204 between the pixels 202. The LED array 200 may be formed from a monolithic segmented device.

The serial interconnection shown in FIG. 2 may use insulation and interconnection associated with additional optical loss, which may cancel the gain in driver cost as the light emitting area is reduced and more power is used for the same amount of illumination as for a non-serially connected LED array. For example, in a chip scale package (CSP) architecture, each pixel may first be isolated before being connected to the cathode of the other pixel.

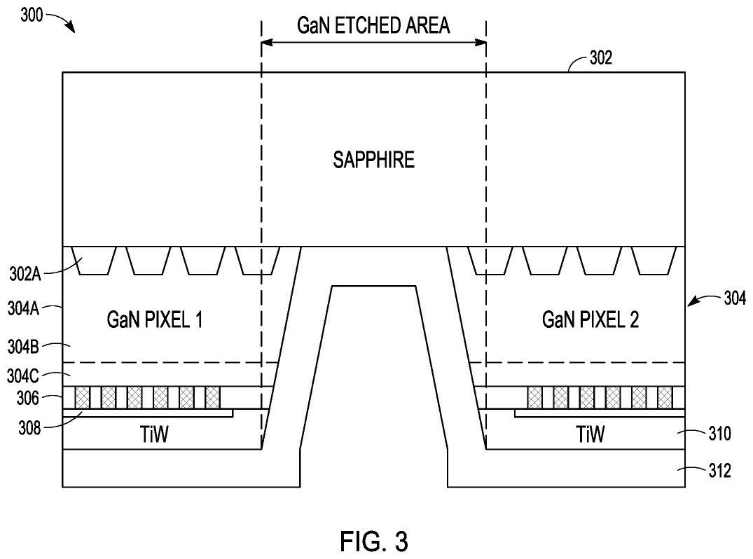

FIG. 3 illustrates isolated pixels, in accordance with some examples. As shown in FIG. 3, the pixels 304 may be formed from, for example, gallium nitride (GaN) on a patterned sapphire substrate 302 (a substrate 302 having patterns 302a). Each pixel 304 has an n-type semiconductor 304a, a p-type semiconductor 304c, and an active region 304b (that emits light of a particular wavelength) between the n-type semiconductor 304a and the p-type semiconductor 304c. A dielectric layer with metal vias 306 is connected to the p-type semiconductor 304c.

To insulate the area of the pixels 304, the n-type and p-type semiconductors 304a-304c that form each LED 300 are fully trenched and the sidewalls 312a of the trench covered by a relatively thick dielectric (insulation) layer 312 that fully overlaps mesa sidewalls. This dielectric layer 312 reduces the area where current is generated by a significant amount as an area is created where current is not injected. The sidewalls 312a may also be inclined, further reducing the area where current is generated. Accordingly, minimization of the optical loss associated with the interconnection area between serially-connected pixels in a high voltage LED array is desirable to avoid cancelling the cost gain provided by the less-expensive driver.

Furthermore, as shown in the example of FIG. 3, a silver (Ag) mirror 308 is fully covered or overlapped by a titanium tin (TiW) layer 310 to avoid Ag contamination. This may be created by pulling the Ag mirror 308 back from the mesa, thereby creating a black belt area where light from the LED is absorbed. Pulling back the Ag mirror 308 may also reduce the area where current is injected uniformly and further reduce efficacy of the high voltage LED.

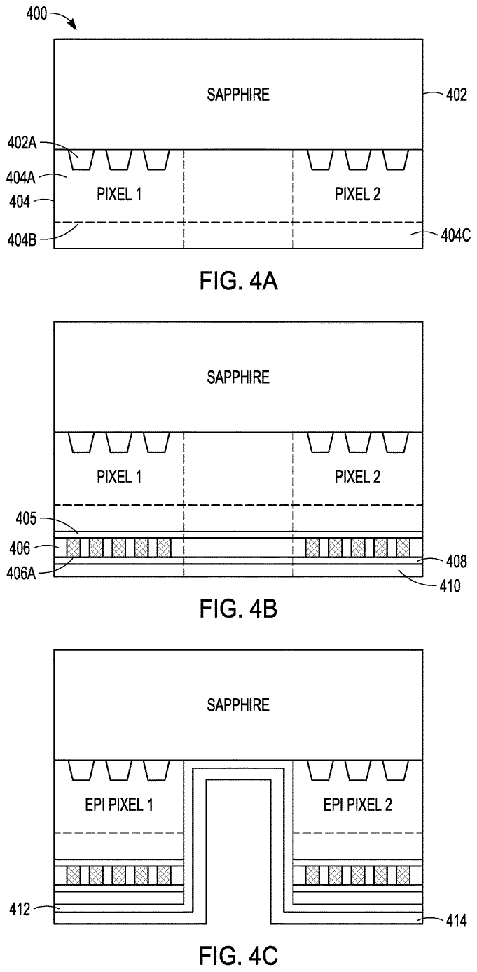

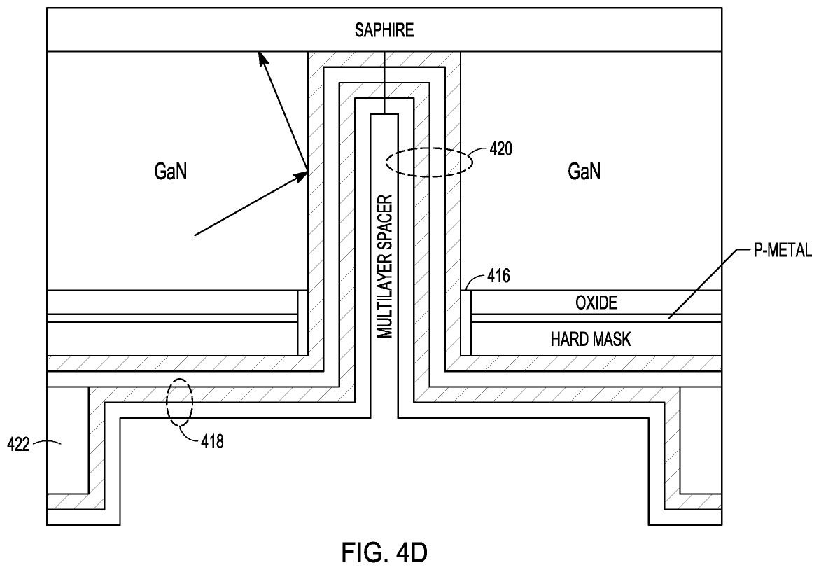

Instead, as shown in FIGS. 4A-4D, an architecture may be used that is based on, for example, a self-aligned SiO2 hard mask, junction spacer, and contact spacer. Such a contact spacer may be an oxide (or other dielectric) deposited on an underlying structure and patterned with a blanket etch, which leaves oxide only on vertical surfaces. A mesa etch is then performed with photoresist only as an etch mask, and a dielectric bilayer is deposited as mesa passivation. In this architecture, overlap of an Ag mirror layer may be avoided, which reduces the dark area between emitting regions. In addition, the mesa is able to be etched without angle, which will reduce the trench area and maximize the effective light emitting area. FIGS. 4A-4D illustrate an N-up (i.e., emission of the LEDs through n-type semiconductor) flip-chip CSP architecture, although other architectures may be used. The device shown in FIGS. 4A-4D is a cross-section of adjacent pixels during fabrication of a monolithic segmented device 400. The monolithic segmented device 400, as described, does not use a tile for current flow.

To obtain a high voltage LED pixel array, multiple pixels are patterned and coupled in series. FIG. 4A illustrates a cross-section of a LED array during fabrication, in accordance with some examples. Note that although specific materials are indicated, the description is not intended to be limited to use of the mentioned materials.

The monolithic segmented device 400 includes multiple semiconductor layers grown on a substrate 402 (e.g., a sapphire substrate) that are to be fabricated into pixels 404. The substrate 402 may be any substrate, such as Sapphire, capable of having epitaxial layers grown thereon. The substrate 402 may have patterns 402a on which the epitaxial layers are grown. The pixels 404 may be formed from gallium nitride (GaN), having an n-type semiconductor 404a adjacent to the substrate 402, a p-type semiconductor 404c, and an active region 404b between the n-type semiconductor 404a and the p-type semiconductor 404c. The active region 404b may be, for example, a multiple quantum well structure in which light is generated for emission from the pixels 404.

As shown by the vertical dotted lines, adjacent pixels 404 may be separated by a narrow trench that has sidewalls within about 20° of parallel to the direction of growth of the epitaxial layers. While reducing the sidewall angles is desirable, a vertical (0°) surface to minimize the gap (i.e., maximize active area) is technologically not feasible-unlike the above angle. This trench provides electrical insulation of each pixel 404. A hard mask may be used, in some embodiments, to permit etching of the n-type and p-type semiconductor layers (among others) to form the trench without formation of a substantially angled sidewall (e.g., greater than about 30°) in the n-type and p-type semiconductor layers to thereby increase the size of the active region 404b.

FIG. 4B illustrates another cross-section of the LED array during fabrication after FIG. 4A, in accordance with some examples. As shown in FIG. 4B, the width of the etching area may be reduced or minimized, e.g., not more than about 5 microns, which may be about the current processing limits today (although narrower widths may be able to be provided in the future). Before etching of the epitaxial GaN layers, CSP die layers allowing uniform current distribution and optical coupling may be deposited. For example, uniform current injection in the p-type semiconductor 404c may be obtained by depositing an Indium Tin Oxide (ITO) layer 405 (or other Transparent Conductive Oxide (TCO) layer) on the p-type semiconductor 404c.

To reduce Ag absorption losses, a dielectric spacer 406, such as SiO2 or SiN and/or other dielectric material, is deposited or otherwise formed on the ITO layer 405. The dielectric spacer 406 may be, for example, between about 300 nm and about 800 nm. An array of openings is etched in a uniform distribution within the dielectric spacer 406 over the ITO layer 405 through lithographic processes (e.g., using a photoresist). A reflective layer 408 (or other optically reflective structure), such as an Ag mirror formed from multiple metals (e.g., Ag—TiW or Ag—Pt), may then be formed on the dielectric spacer 406. The reflective layer 408 may be, for example, between about 100 nm and about 300 nm. The material forming the reflective layer 408 may fill the openings in the dielectric spacer 406 to form eVias 406a and electrically connect the ITO layer 405 and the reflective layer 408. Thus, the e Vias 406a may provide uniform current distribution over the area of the p-type semiconductor 404c. The diameter of the eVias 406a may be, for example, between about 5 microns to about 10 microns. The dielectric spacer 406 may combine several different dielectrics to form a composite mirror to reduce light reflected by the Ag mirror and hence lower absorption losses by the Ag mirror. The addition of the composite mirror provides total internal reflection (TIR) at the SiO2/GaN interface to enhance reflection and, as the Ag mirror is not in contact with the p-GaN, a transparent spreading current layer (the ITO layer) is used on the p-GaN.

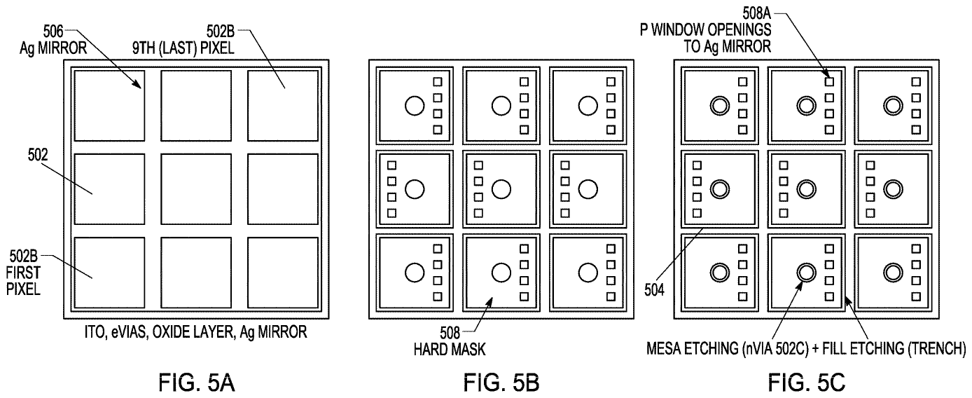

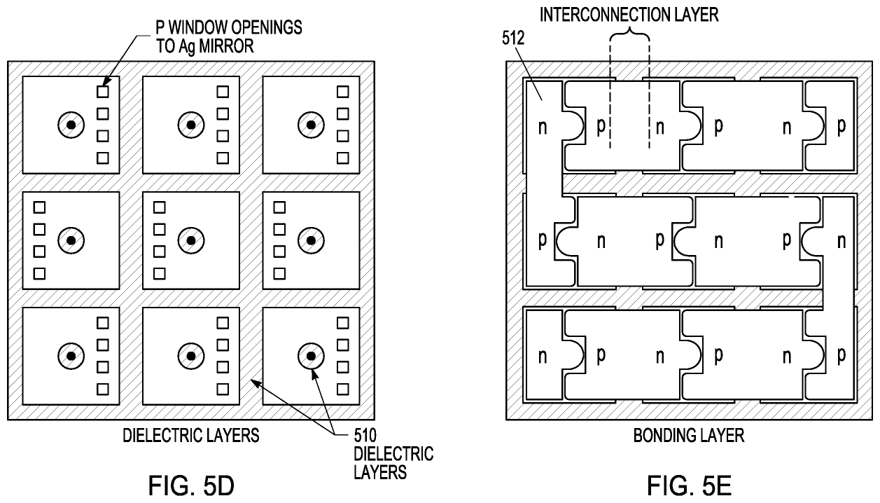

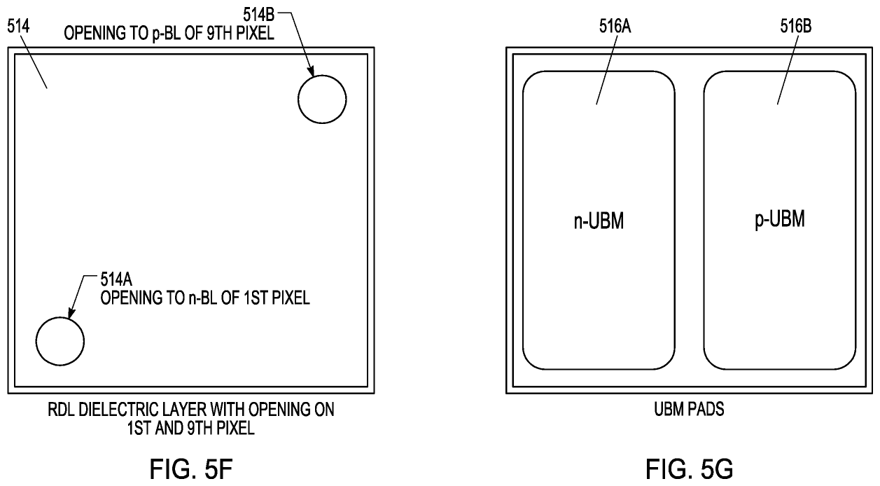

A hard mask 410 is then deposited on the reflective layer 408. The hard mask 410 may be formed from a material substantially denser than a polymer, for example, SiO2, SiC, or aluminum nitride (AlN). The hard mask 410 may be, for example, between about 1000 nm and about 3000 nm The hard mask 410 may have openings to allow current injection from the p-bonding layer (p-BL) to the reflective layer 408 (as shown in FIG. 5C). The hard mask 410 may have openings to allow current injection from a p-bonding layer (p-BL) to the reflective layer 408 and thus the p-type semiconductor 404c, and from an n-bonding layer (n-BL) to the n-type semiconductor 404a (as shown in FIG. 5C).

FIG. 4C illustrates another cross-section of the LED array during fabrication after FIG. 4B, in accordance with some examples. As shown, the hard mask 410 is used to permit etching of the trench, as well as connections to the n-type semiconductor 404a. Note that although (wet or dry) etching is referred to, other techniques may be used to form various layers such as laser drilling, ion-beam formation, etc. To then insulate the pixels 404, a first sidewall dielectric layer 412, such as SiO2, may be deposited on the sidewalls of the pixel 404. A second sidewall dielectric layer 414 may be deposited on the first sidewall dielectric layer 412, leaving a gap between opposing second sidewall dielectric layers 414 within the trench. The second sidewall dielectric layer 414 may be used to planarize the first sidewall dielectric layer 412 and to avoid crack propagation within the first sidewall dielectric layer 412 during further processing. In some embodiments, the first sidewall dielectric layer 412 and the second sidewall dielectric layer 414 may be formed on the hard mask 410. The first sidewall dielectric layer 412 and the second sidewall dielectric layer 414 may be substantially conformal as shown-with the gap between the opposing second sidewall dielectric layers 414 within the trench filled with additional material (dielectric and/or conductive) during further processing operations. The first sidewall dielectric layer 412 and the second sidewall dielectric layer 414 may be, for example, between about 80 nm and about 800 nm (first sidewall dielectric layer 412) and about 20 nm and about 500 nm (second sidewall dielectric layer 414) respectively.

Although the first sidewall dielectric layer 412 and the second sidewall dielectric layer 414 is formed within the trench, they may fully fill the trench or, as shown in FIG. 4C, only partially fill the trench. In some embodiments, the dielectric spacer 406, reflective layer 408, and hard mask 410 may be etched back, and a thin dielectric spacer 416 (shown in FIG. 4D) may be deposited to separate these layers from the first sidewall dielectric layer 412. The dielectric spacer 416 may be, for example, between about 100 nm and about 400 nm

FIG. 4D illustrates another cross-section of the LED array during fabrication after FIG. 4C, in accordance with some examples. The first sidewall dielectric layer 412 and second sidewall dielectric layer 414, along with additional dielectric layers 418 disposed thereon, may form a spacer layer stack 420 at the trench sidewalls to form a one-dimensional photonic Bragg reflector to increase or maximize light reflection of light emitted by the active region 404b and hence enhance light extraction efficiency from each pixel. The dielectric layers 418 may be, for example, between about 80 nm and about 800 nm. As shown, the first sidewall dielectric layer 412 and the second sidewall dielectric layer 414 may be disposed on the hard mask 410, while the additional dielectric layers 418 may be disposed on (and contact) a bonding layer 422 on the hard mask 410 as well as contacting the second sidewall dielectric layer 414. In other embodiments, a single dielectric may be used to partially or completely fill the trench. In this case of a single dielectric layer, a conductive layer may be disposed on the single dielectric layer to promote reflection into the semiconductor layers. The trench may be on the order of several microns (e.g., up to about 10 microns), while the sidewall dielectric layers may be considerably thinner, e.g., up to about a few tenths of a micron. The thickness of the sidewall dielectric layers may be dependent on the desired index of refraction created by the structure.

FIG. 5A illustrates a top view of a high voltage LED array during fabrication, in accordance with some examples. The LED array 500 is shown as being formed from GaN semiconductors, however, any semiconductor capable of light emission may be used in other embodiments. The LED array 500 shown in FIG. 5A has a grid of areas to be formed into pixels 502 via etching trenches 504 that extend to the substrate (i.e., the semiconductor layers are fully etched). Additional layers described above not shown in FIG. 5A include, for example, an ITO layer, as well as oxide (and/or other dielectric) layer and Ag mirror (in addition to the dielectric layers) as shown in FIGS. 4A-4D. As above, the oxide layer may, in some embodiments, be used as a spacer (along with other dielectric layers) to act as a composite mirror and reduce Ag absorption losses by enabling TIR at the GaN/SiO2 interface. The pixels 502 are to be coupled in series from a first pixel 502a to a last pixel 502b after fabrication and an nVia 502c (via to electrically contact the n-GaN) disposed in the center of each pixel 502, as shown in FIG. 5C. That is, as shown in FIG. 5A, the GaN semiconductor layers are to be fully etched in a grid pattern to define 9 insulated pixels 502 (also referred to as segments) formed in a rectangular (square) shape. This number, as the shape of each pixel 502, may vary—e.g., one or more of the pixels may have a rectangular shape having at least one dimension different from one or more other of the pixels. In some embodiments, the Ag mirror (p metal) and hard mask are patterned together. Alternatively, the hard mask may instead be patterned during mesa etching. Independent of this, note that an oxide may be used as a “guard sheet” instead of a relatively thicker and bulkier material such as TiW. The diameter of the nVia 502c may be, for example, between about 5 microns to about 50 microns.

FIG. 5B illustrates a top view of the high voltage LED array during fabrication after FIG. 5A, in accordance with some examples. The hard mask layer 508 is deposited on the structure formed after FIG. 5A.

FIG. 5C illustrates a top view of the high voltage LED array during fabrication after FIG. 5B, in accordance with some examples. The structure in FIG. 5C is formed after the etching described above. As shown in FIG. 5C, hard mask layers 508 of the 2nd row of pixels 502 have p-window openings 508a to the Ag mirror 506 on the left side, whereas bonding layers of the 1st and 3rd row of pixels 502 have p-window openings 508a on the right side. That is, the p-window openings 508a of the 2nd row of pixels 502 are fabricated on an opposite side of each pixel 502 as the p-window openings 508a of the 1st and 3rd row of pixels 502 (i.e., sides on which the p-window openings 508a are fabricated alternate with the row of pixels 502). This geometry permits electrical contact. The p-GaN is etched to allow direct contact to the n-GaN through the nVias 502c.

FIG. 5D illustrates a top view of the high voltage LED array during fabrication after FIG. 5C, in accordance with some examples. As shown in FIG. 5D, dielectric layers 510 are deposited to fill the trench 504 and insulate each pixel 502. One or more dielectric layers are also deposited around the periphery of each nVia 502c for insulation.

FIG. 5E illustrates a top view of the high voltage LED array during fabrication after FIG. 5D, in accordance with some examples. Multiple bonding layers 512 are deposited on the structure. As shown in FIG. 5E, one of the bonding layers 512 has an n polarity (n-bonding layer) and another of the bonding layers 512 has a p polarity (p-bonding layer) for each pixel 502. The bonding layers 512 extend between adjacent pixels 502 (over the trenches 504) to couple the p region of one of the adjacent pixels 502 to the n region of the other of the adjacent pixels 502. The bonding layers 512 are used to uniformly distribute the current in the n-type and p-type semiconductor layers. The bonding layers 512 may be formed from copper (Cu) and/or Al, for example. In one example, the n-bonding layer of a given pixel 502 connects to the n-type GaN through the center nVia 502c. However, other n-contact layouts are possible. For example, the n-bonding layer can be contacted by multiple (e.g., 4) nVias distributed in the 4 corners of each pixel 502. As an alternative, an n-contact can be formed on 1 or more pixel mesa sides (as shown in FIGS. 4C and 4D). Such an n-contact on 1 or more pixel mesa sides may be combined with the n-contact in the pixel area (nVia). The total number of n-contact areas may be selected so that the product of electrical losses and optical losses is minimized. As shown in FIG. 5E, a series connection is be obtained by connecting the p-bonding layer of one pixel 502 to the n bonding layer of the following pixel 502. This interconnection may be formed on one side of each pixel 502 and may be the universal for each pixel 502. Only the bonding layer of the first and last pixel of each row or column will have n contact on different pixel sides to allow serial connection between following row or column.

FIG. 5F illustrates a top view of the high voltage LED array during fabrication after FIG. 5E, in accordance with some examples. As shown in FIG. 5G, a redistribution (RDL) dielectric layer 514 is deposed over the entire pixel area. The RDL dielectric layer 514 may be limited to only 2 openings 514a, 514b: an n-opening 514a on the area corresponding to the n-BL of the 1st pixel 502 and a p-opening 514b on the area corresponding to the p-BL of the 9th (last) pixel 502. The diameter of the openings 514a, 514b may be, for example, between about 20 microns to about 70 microns.

FIG. 5G illustrates a top view of the high voltage LED array during fabrication after FIG. 5F, in accordance with some examples. As shown in FIG. 5G, Under Bump Metallurgy (UBM) is deposited on the RDL dielectric layer 514. In particular, a n-UBM pad 516a and a p-UBM pad 516b may be deposited on the corresponding n-opening 514a and p-opening 514b.

Comparing the interconnection area between the architecture shown in FIG. 2 and that shown in FIGS. 4C and 4D, the width of the trench area between the pixels is substantially larger in FIG. 2 than in FIGS. 4C and 4D. The width of the trench area between pixels determines the area where current is generated. For a given die area, the high voltage die architecture shown in FIGS. 4C and 4D may permit a smaller GaN trench width and current injection closer to the trench. As a result, for the same die area (compared with FIG. 2), the area where current is generated is higher and optical losses lower for the high voltage die.

Each of the LEDs in a light source may be formed from one or more inorganic materials (e.g., binary compounds such as gallium arsenide (GaAs), ternary compounds such as aluminum gallium arsenide (AlGaAs), quaternary compounds such as indium gallium phosphide (InGaAsP), gallium nitride (GaN), or other suitable materials), usually either III-V materials (defined by columns of the Periodic Table) or II-VI materials. Each of the LEDs may emit light in the visible spectrum (about 400 nm to about 800 nm). In some embodiments, one or more other layers, such as a phosphor layer may be disposed on each of the one or more LED arrays to convert the light from the LEDs into white (or another color) light.

In some embodiments, at least some of the LEDs may emit light in the infrared spectrum (above about 800 nm) LEDs. In this case, LEDs that emit light in the infrared spectrum may be, for example, interspersed with LEDs that emit light in the visible spectrum, or each type of LED (visible emitter/infrared emitter) may be disposed on different sections of a particular array. Alternatively, each LED array may only emit light in either the visible spectrum or the infrared spectrum; separate (one or more) LED arrays may be used to emit light in the infrared spectrum, each of the LEDs may be controllable by a processor.

Each of the LEDs may be a microLED or may be larger than a microLED. A microLED array may include thousands to millions of microscopic LEDs that may emit light and that may be individually controlled or controlled in groups of pixels (e.g., 5×5 groups of pixels). MicroLEDs are small (e.g., <0.01 mm on a side) and may provide monochromatic or multi-chromatic light, typically red, green, blue, or yellow using inorganic semiconductor material such as that indicated above.

The light source may include at least one lens and/or other optical elements such as reflectors. The lens and/or other optical elements may direct the light emitted by the one or more LED arrays towards one or more locations to be illuminated.

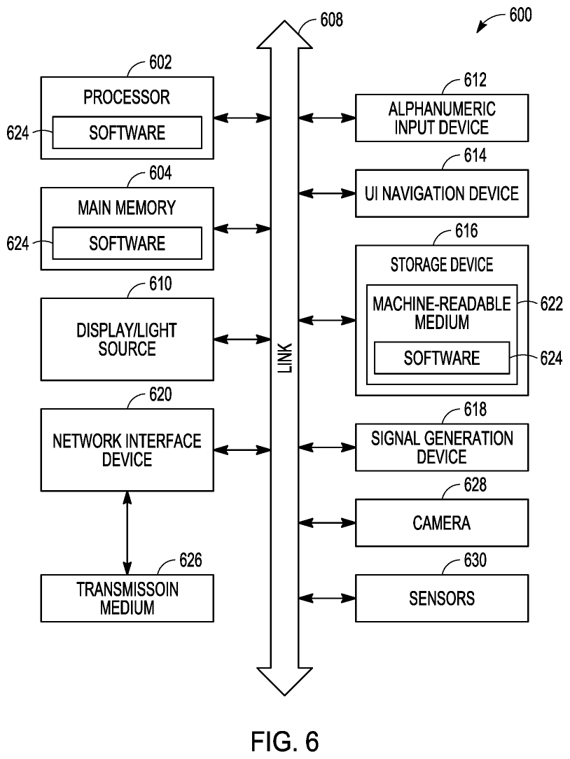

FIG. 6 illustrates an example of a general device in accordance with some embodiments. The device 600 may be a mobile device such as a laptop computer (PC), a tablet PC, or a smart phone, or an automotive device, for example. Various elements may be provided on the backplane indicated above, while other elements may be local or remote. Examples, as described herein, may include, or may operate on, logic or a number of components, modules, or mechanisms.

Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The electronic device 600 may include a hardware processor (or equivalently processing circuitry) 602 (e.g., a central processing unit (CPU), a GPU, a hardware processor core, or any combination thereof), a memory 604 (which may include main and static memory), some or all of which may communicate with each other via an interlink (e.g., bus) 608. The memory 604 may contain any or all of removable storage and non-removable storage, volatile memory or non-volatile memory. The electronic device 600 may further include a display/light source 610 such as the LED array described above, or a video display, an alphanumeric input device 612 (e.g., a keyboard), and a user interface (UI) navigation device 614 (e.g., a mouse). In an example, the display/light source 610, input device 612 and UI navigation device 614 may be a touch screen display. The electronic device 600 may additionally include a storage device (e.g., drive unit) 616, a signal generation device 618 (e.g., a speaker), a network interface device 620, one or more cameras 628, and one or more sensors 630, such as a global positioning system (GPS) sensor, compass, accelerometer, or other sensor such as those described herein. The electronic device 600 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 616 may include a non-transitory machine readable medium 622 (hereinafter simply referred to as machine readable medium) on which is stored one or more sets of data structures or instructions 624 (e.g., software) embodying or utilized by any one or more of the techniques or functions described herein. The instructions 624 may also reside, completely or at least partially, within the memory 604 and/or within the hardware processor 602 during execution thereof by the electronic device 600. While the machine readable medium 622 is illustrated as a single medium, the term “machine readable medium” may include a single medium or multiple media (e.g., a centralized or distributed database, and/or associated caches and servers) configured to store the one or more instructions 624.

The term “machine readable medium” may include any medium that is capable of storing, encoding, or carrying instructions for execution by the electronic device 600 and that cause the electronic device 600 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions 624 may further be transmitted or received over a communications network using a transmission medium 626 via the network interface device 620 utilizing any one of a number of wireless local area network (WLAN) transfer protocols (e.g., frame relay, internet protocol (IP), transmission control protocol (TCP), user datagram protocol (UDP), hypertext transfer protocol (HTTP), etc.) or the SPI or CAN bus. Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as Institute of Electrical and Electronics Engineers (IEEE) 902.11 family of standards known as Wi-Fi, IEEE 902.16 family of standards known as WiMax, IEEE 902.16.4 family of standards, a Long Term Evolution (LTE) family of standards, a Universal Mobile Telecommunications System (UMTS) family of standards, peer-to-peer (P2P) networks, a next generation (NG)/6th generation (6G) standards among others. In an example, the network interface device 620 may include one or more physical jacks (e.g., Ethernet, coaxial, or phone jacks) or one or more antennas to connect to the transmission medium 626.

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical central processing unit (CPU), a single-or multi-core processor, and/or any other device capable of executing or otherwise operating computer-executable instructions, such as program code, software modules, and/or functional processes.

The camera 628 may sense light at least the wavelength or wavelengths emitted by the LEDs. The camera 628 may include optics (e.g., at least one camera lens) that are able to collect reflected light of illumination that is reflected from and/or emitted by an illuminated region. The camera lens may direct the reflected light onto a multi-pixel sensor (also referred to as a light sensor) to form an image of on the multi-pixel sensor.

The processor 602 may control and drive the LEDs via one or more drivers. For example, the processor 602 may optionally control one or more LEDs in LED arrays independent of another one or more LEDs in the LED arrays, so as to illuminate an area in a specified manner.

In addition, the sensors 630 may be incorporated in the camera 628 and/or the light source 610. The sensors 630 may sense visible and/or infrared light, and may further sense the ambient light and/or variations/flicker in the ambient light in addition to reception of the reflected light from the LEDs. The sensors may have one or more segments (that are able to sense the same wavelength/range of wavelengths or different wavelength/range of wavelengths), similar to the LED arrays.

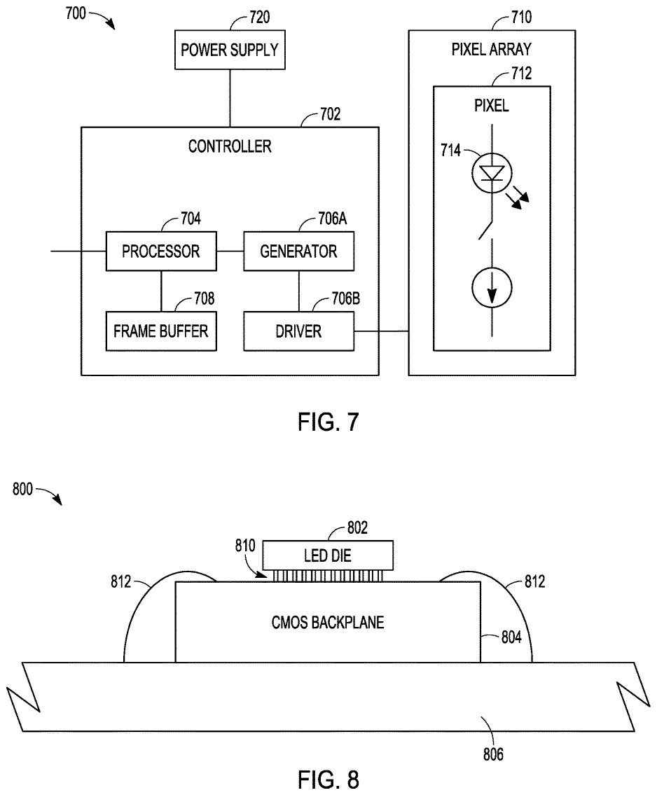

FIG. 7 illustrates an example lighting system, according to some embodiments. As above, some of the elements shown in the lighting system 700 may not be present, while other additional elements may be disposed in the lighting system 700. The lighting system 700 may include a controller 702 that controls illumination using a pixel array 710 that contains multiple individual pixels 712.

In some embodiments, some or all of the components described as the controller 702 may be disposed on a backplane such as, for example, a complementary metal oxide semiconductor (CMOS) backplane. In some embodiments, each single pixel driven by the CMOS backplane may be formed from a single high voltage die. The controller 702 may be coupled to or include one or more processors 704. The processor 704 may receive image data (in frames) via an interface and may process the image data to control a generator 706a, for example, controlling analog signals or PWM duty cycles and/or turn-on times for causing the lighting system 700 to produce the images indicated by the image data.

The controller 702 may further include a frame buffer 708. The frame buffer 708 may store one or more images prior the one or more processors 704 and store the indications for implementation by the one or more processors 704.

The generator 706a may be controlled by the processor 704 and may produce driving signals in accordance with the indications. The generator 706a may be connected to a driver 706b (such as that described in FIG. 2) to drive the pixel array 710 so that the pixels 712 provide desired intensities of light.

Each pixel 712 may include one or more LEDs 714. The LEDs 714 may be different colors and may be controlled individually or in groups. As shown, the pixel 712 may include, for each pixel 712 or LED 714, a PWM switch, and a current source. The pixel 712 may be driven by the driver 706b. The signal from the generator 706a may cause the switch to open and close in accordance with the value of the signal. The signal corresponding to the intensities of light may cause the current source to produce a current flow to cause the pixels 712 to produce the corresponding intensities of light.

The lighting system 700 may further include a power supply 720. In some embodiments, the power supply 720 may be a battery that produces power for the controller 702.

FIG. 8 illustrates an example hardware arrangement for implementing the above disclosed subject matter, according to some embodiments. In particular, the hardware arrangement 800 may include an LED die 802 that contains the LED array(s) and a backplane, such as a CMOS backplane 804. The LED die 802 may be coupled to the CMOS backplane 804 by one or more interconnects 810, where the interconnects 810 may provide for transmission of signals between the LED die 802 and the CMOS backplane 804. The interconnects 810 may comprise one or more solder bump joints, one or more copper pillar bump joints, other types of interconnects known in the art, or some combination thereof.

The LED die 802 may include circuitry to implement the LED array described above. In particular, the LED die 802 may include a plurality of LEDs. The LED die 802 may include a shared active layer and a shared substrate for the LED array, and thereby the LED array may be a monolithic LED array. Each LED of the LED array may include an individual segmented active layer and/or substrate. In some embodiments, the LED die 802 may further include switches and current sources to drive the LED array as described above. In other embodiments, the switches and the current sources may be included in the CMOS backplane 804. The LEDs may be micro-LEDs or LEDs larger than micro-LEDs.

The CMOS backplane 804 may include circuitry to implement the control module. The CMOS backplane 804 may utilize the interconnects 810 to provide the LED array with the driving signals and the signals for the intensity for causing the LED array to produce light in accordance with the signals and the intensity.

The hardware arrangement 800 may further include a PCB 806. The PCB 806 may include circuitry to implement various functionality described herein. The PCB 806 may be coupled to the CMOS backplane 804. For example, the PCB 806 may be coupled to the CMOS backplane 804 via one or more wire bonds 812. The PCB 806 and the CMOS backplane 804 may exchange image data, power, and/or feedback via the coupling, among other signals. The LED die 802 and the CMOS backplane 804 may form a hybridized die on the PCB 806.

As shown, the LEDs and circuitry supporting the LED array can be packaged and include a submount or printed circuit board for powering and controlling light production by the LEDs. The PCB supporting the LED array may include electrical vias, heat sinks, ground planes, electrical traces, and flip chip or other mounting systems. The submount or PCB may be formed of any suitable material, such as ceramic, silicon, aluminum, etc. If the submount material is conductive, an insulating layer may be formed over the substrate material, and a metal electrode pattern formed over the insulating layer for contact with the micro-LED array. The submount can act as a mechanical support, providing an electrical interface between electrodes on the LED array and a power supply, and also provide heat sink functionality.

In general, a variety of applications may be supported by LED arrays. Such applications may include stand-alone applications to provide general illumination (e.g., within or external to a room or vehicle) or to provide specific images. In addition to devices such as a luminaire, projector, mobile device, the system may be used to provide either augmented reality (AR) and virtual reality (VR)-based applications. Visualization systems, such as VR and AR systems, are becoming increasingly more common across numerous fields such as entertainment, education, medicine, and business. Various types of devices may be used to provide AR/VR to users, including headsets, glasses, and projectors. Such an AR/VR system may include components similar to those described above: the micro-LED array, a display or screen (which may include touchscreen elements), a micro-LED array controller, sensors, and a controller, among others. The AR/VR components can be disposed in a single structure, or one or more of the components shown can be mounted separately and connected via wired or wireless communication. Power and user data may be provided to the controller. The user data input can include information provided by audio instructions, haptic feedback, eye or pupil positioning, or connected keyboard, mouse, or game controller. The sensors may include cameras, depth sensors, audio sensors, accelerometers, two or three axis gyroscopes and other types of motion and/or environmental/wearer sensors that provide the user input data. Other sensors can include but are not limited to air pressure, stress sensors, temperature sensors, or any other suitable sensors for local or remote environmental monitoring. In some embodiments, the control input can include detected touch or taps, gestural input, or control based on headset or display position. As another example, based on the one or more measurement signals from one or more gyroscope or position sensors that measure translation or rotational movement, an estimated position of the AR/VR system relative to an initial position can be determined.

In some embodiments, the controller may control individual micro-LEDs or one or more groups of LEDs to display content (AR/VR and/or non-AR/VR) to the user while controlling other LEDs and sensors used in eye tracking to adjust the content displayed. Content display LEDs may be designed to emit light within the visible band (approximately 400 nm to 890 nm) while LEDs used for tracking may be designed to emit light in the IR band (approximately 890 nm to 2,200 nm). In some embodiments, the tracking LEDs and content LEDs may be simultaneously active. In some embodiments, the tracking LEDs may be controlled to emit tracking light during a time period that content LEDs are deactivated and are thus not displaying content to the user. The AR/VR system can incorporate optics, such as those described above, and/or an AR/VR display, for example to couple light emitted by LED array onto the AR/VR display.

In some embodiments, the AR/VR controller may use data from the sensors to integrate measurement signals received from the accelerometers over time to estimate a velocity vector and integrate the velocity vector over time to determine an estimated position of a reference point for the AR/VR system. In other embodiments, the reference point used to describe the position of the AR/VR system can be based on depth sensor, camera positioning views, or optical field flow. Based on changes in position, orientation, or movement of the AR/VR system, the system controller can send images or instructions the light emitting array controller. Changes or modification the images or instructions can also be made by user data input, or automated data input.

In general, in a VR system, a display can present to a user a view of scene, such as a three-dimensional scene. The user can move within the scene, such as by repositioning the user's head or by walking. The VR system can detect the user's movement and alter the view of the scene to account for the movement. For example, as a user rotates the user's head, the system can present views of the scene that vary in view directions to match the user's gaze. In this manner, the VR system can simulate a user's presence in the three-dimensional scene. Further, a VR system can receive tactile sensory input, such as from wearable position sensors, and can optionally provide tactile feedback to the user.

In an AR system, on the other hand, the display can incorporate elements from the user's surroundings into the view of the scene. For example, the AR system can add textual captions and/or visual elements to a view of the user's surroundings. For example, a retailer can use an AR system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the AR system can position a virtual chair in a room. The user can stand in the room on a front side of the virtual chair location to view the front side of the chair. The user can move in the room to an area behind the virtual chair location to view a back side of the chair. In this manner, the AR system can add elements to a dynamic view of the user's surroundings.

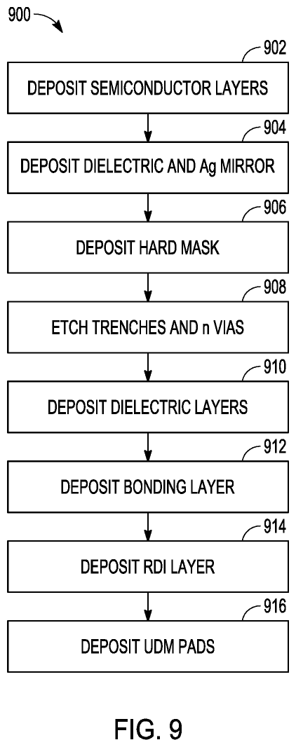

FIG. 9 illustrates an example method of fabricating an illumination device, according to some embodiments. Not all of the operations may be undertaken in the method 900, and/or additional operations may be present. The operations may occur in a different order from that indicated in FIG. 9.

At operation 902, semiconductor layers are deposited or otherwise formed on a substrate. The semiconductor layers may include both n-type and p-type GaN layers (n-GaN, p-GaN), with an active layer therebetween to emit light.

At operation 904, one or more dielectric layers and a mirror structure (e.g., Ag mirror) may be deposited or otherwise formed on the p-GaN. eVias may be disposed in the dielectric layers. The mirror structure may reflect light emitted by the active region back towards the n-GaN to be emitted from the pixel surface.

At operation 906, a hard mask spacer is deposited or otherwise formed on the mirror structure. The hard mask spacer may have one or more p-window openings to the underlying mirror structure. The relative position of the p-window openings may vary dependent on the pixel/row of pixels.

At operation 908, vertical or substantially vertical trenches (having sidewalls in the direction of epitaxial growth) are etched through the hard mask spacer, the one or more dielectric layers, the mirror structure, and the semiconductor layers to isolate pixels. In addition, nVias are etched in each pixel to contact the n-GaN layer. The pixels may be uniformly formed in squares or rectangles or other shapes. The number of pixels in the array may be 1×2 or larger (e.g., 3×3 as shown in FIGS. 5A-5F.

At operation 910, dielectric layers may be deposited or otherwise formed on the hard mask. P-window openings may be formed in the dielectric layers. The dielectric layers are deposited or otherwise formed to fill the trench and insulate each pixel. One or more dielectric layers are also deposited around the periphery of each nVia for insulation.

At operation 912, n- and p-bonding layers are formed on the dielectric layers. The bonding layers uniformly distribute the current in the n-GaN and p-GaN and serially connect the pixels in the array.

At operation 914, an RDL dielectric layer is deposed or otherwise formed over the entire array. The RDL dielectric layer may have an n-opening on the area corresponding to the n-BL of the 1st pixel and a p-opening on the area corresponding to the p-BL of the last pixel.

At operation 916, an n-UBM pad and a p-UBM pad are deposited or otherwise formed on the corresponding n-opening and p-opening to allow current to drive the array.

This method 900 may be used to form a high voltage die (e.g., >6V) with several segments/pixels (>2) coupled in series. In such a structure, the trench between segments may be formed with a hard mask spacer instead of titanium tin (TiW) and the bonding layer is used to form the serial interconnection between segments.

While only certain features of the system and method have been illustrated and described herein, many modifications and changes will occur to those skilled in the art. It is, therefore, to be understood that the appended claims are intended to cover all such modifications and changes. Method operations may be performed substantially simultaneously or in a different order.

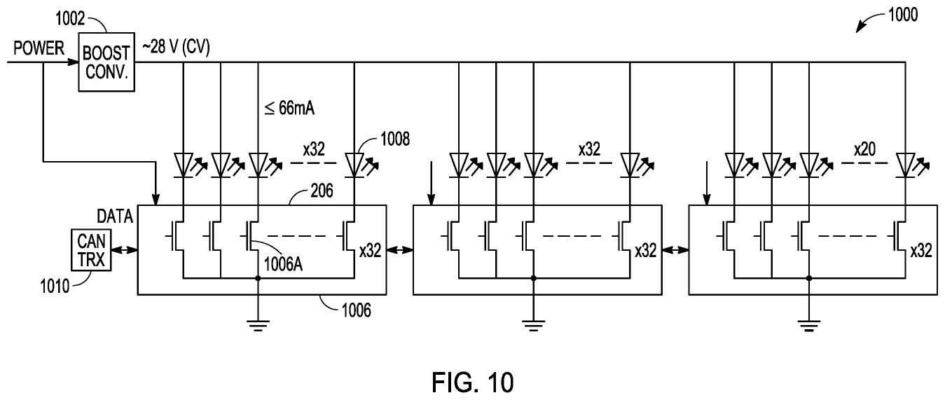

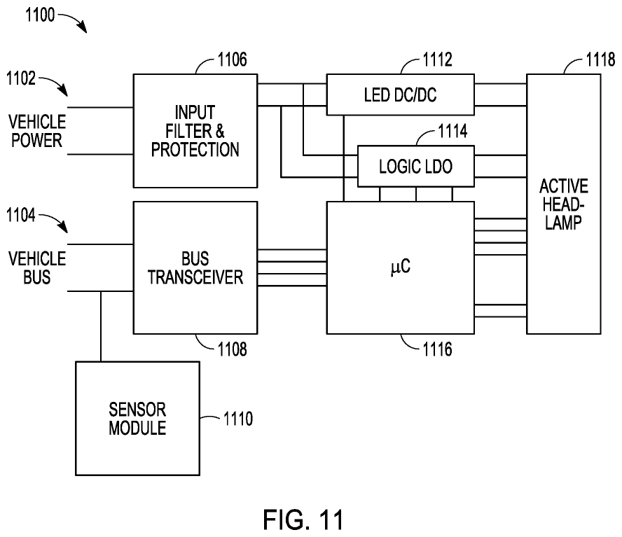

FIG. 10 illustrates another driver architecture, in accordance with some examples. The driver architecture 1000 of FIG. 10 may use a lower power booster converter 1002 that increases the battery voltage of typically 8-12V to about, for example, 27-28V to provide a constant array voltage at a current of less than about 66 mA to the LEDs 1008 (e.g., about 56 mA). Instead of a large number of matrix drivers being used to individually control the LEDs 1008, a smaller number of backlight unit (BLU) drivers 1006 may be used to drive the same number of LEDs 1008.

Each BLU driver 1006 may be connected with a larger number of LEDs 1008 than a matrix driver (as shown in FIG. 10, most of the BLU drivers 1006 are connected to 32 LEDs). In some embodiments, the number of LEDs may be equally distributed such that each BLU driver 1006 is coupled to the same number of LEDs 1008; in other embodiments, such as that in FIG. 10, at least one of the BLU driver 1006 has a different number of LEDs 1008 coupled thereto than at least one other BLU driver 1006. Each BLU driver 1006 may have a channel that contains a switch 1006a for each LED 1008. As shown, the LEDs 1008 are coupled in parallel between the boost converter 1002 and the associated BLU driver 1006 (and ground). A digital serial interface connected to a vehicle CAN bus 1010 is connected to each BLU driver 1006 and used to individually control driving of each LED 1008 in the BLU driver 1006.

In some embodiments, each LED 1008 connected with the BLU driver 1006 may be controlled in a hybrid manner. That is, each LED 1008 connected with the BLU driver 1006 may be controlled using, for example, both analog and digital (pulse width modulation (PWM)) signals. For example, the analog or PWM signals may be used to dim, rather than entirely deactivate, an individual LED 1008. Each of the analog and PWM signals may be provided by a different signal generator. The switch 1006a may be a transconductance device such as a metal-oxide-semiconductor (MOS) transistor. The switch 1006a may operate in a nearly saturated state to permit operation in either analog or digital mode and provide increased dimming options. In addition, due to the parallel arrangement of the LEDs 1008, the driver architecture 1000 of FIG. 10 may enjoy built-in protection against open and shorting of the LEDs 1008. That is, one of the LEDs 1008 being open or shorted does not affect operation of others of the LEDs 1008.

Each BLU driver 1006 uses a low-dropout (LDO) voltage current source (one or more linear regulators) in series with the LEDs to individually control the current and the on/off time of each LED, as above hybrid driving.

The driver architecture 1000 of FIG. 10 may also permit vertical synchronization (VSYNC). Every time a new frame (image) is to be displayed, the data used to generate the frame is followed by a VSYNC pulse to reset the row/column logic and make the display ready for the next frame. The backplane acts as a display driver where frames are loaded, so the driver architecture 1000 uses a VSYNC pulse. In some headlamp applications, the LED array (which, as used herein may include microLEDs and/or larger LEDs) and M×N driver are combined to illuminate different portions of the road, data sent to both the LED array and M×N driver is synchronized. The BLU drivers 1006 have VSYNC inputs, which simplifies incorporation and use of VSYNC in the driver architecture 1000.

Similarly, a serial peripheral interface (SPI) bus is typically a point-to-point serial bus. However, pass-through may be used in an integrated circuit (IC) connected to the SPI bus so that more than one device can be controlled. A pass-through input may be available for the BLU drivers 1006. Thus, in some embodiments, a single SPI bus interface may be used to control a larger number of BLU drivers 1006.

FIG. 11 is a diagram of an example vehicle headlamp system 1100. The example vehicle headlamp system 1100 illustrated in FIG. 11 includes power lines 1102, a data bus 1104, an input filter and protection module 1106, a bus transceiver 1108, a sensor module 1110, an LED direct current to direct current (DC/DC) module 1112, a logic low-dropout (LDO) module 1114, a micro-controller 1116 and an active headlamp 1118. In embodiments, the active headlamp 1118 may include an LED lighting system. In some embodiments, some electronic components of some or all of the modules in the vehicle lighting system 1100 may be accommodated on the top surface of the LED lighting system and some may be provided on the circuit board.

The power lines 1102 may have inputs that receive power from a vehicle, and the data bus 1104 may have inputs/outputs over which data may be exchanged between the vehicle and the vehicle headlamp system 1100. For example, the vehicle headlamp system 1100 may receive instructions from other locations in the vehicle, such as instructions to turn on turn signaling or turn on headlamps, and may send feedback to other locations in the vehicle if desired. The sensor module 1110 may be communicatively coupled to the data bus 1104 and may provide additional data to the vehicle headlamp system 1100 or other locations in the vehicle related to, for example, environmental conditions (e.g., time of day, rain, fog, or ambient light levels), vehicle state (e.g., parked, in-motion, speed of motion, or direction of motion), and presence/position of other objects (e.g., vehicles or pedestrians). A headlamp controller that is separate from any vehicle controller communicatively coupled to the vehicle data bus may also be included in the vehicle headlamp system 1100. In FIG. 11, the headlamp controller may be a micro-controller, such as micro-controller (pc) 1116. The micro-controller 1116 may be communicatively coupled to the data bus 1104.

The input filter and protection module 1106 may be electrically coupled to the power lines 1102 and may, for example, support various filters to reduce conducted emissions and provide power immunity. Additionally, the input filter and protection module 1106 may provide electrostatic discharge (ESD) protection, load-dump protection, alternator field decay protection, and/or reverse polarity protection.

The LED DC/DC module 1112 may be coupled between the filter and protection module 1106 and the active headlamp 1118 to receive filtered power and provide a drive current to power LEDs in the LED array in the active headlamp 1118. The LED DC/DC module 1112 may have an input voltage between 7 and 18 volts with a nominal voltage of approximately 3.2 volts and an output voltage that may be slightly higher (e.g., 0.3 volts) than a maximum voltage for the LED array (e.g., as determined by factor or local calibration and operating condition adjustments due to load, temperature or other factors).

The logic LDO module 1114 may be coupled to the input filter and protection module 1106 to receive the filtered power. The logic LDO module 1114 may also be coupled to the micro-controller 1116 and the active headlamp 1118 to provide power to the micro-controller 1116 and/or the silicon backplane (e.g., CMOS logic) in the active headlamp 1118.

The bus transceiver 1108 may have, for example, a universal asynchronous receiver transmitter (UART) or serial peripheral interface (SPI) interface and may be coupled to the micro-controller 1116. The micro-controller 1116 may translate vehicle input based on, or including, data from the sensor module 1110. The translated vehicle input may include a video signal that is transferrable to an image buffer in the active headlamp 1118. In addition, the micro-controller 1116 may load default image frames and test for open/short pixels during startup. In embodiments, an SPI interface may load an image buffer in CMOS.

Image frames may be full frame, differential or partial frames. Other features of micro-controller 1116 may include control interface monitoring of CMOS status, including die temperature, as well as logic LDO output. In embodiments, LED DC/DC output may be dynamically controlled to minimize headroom. In addition to providing image frame data, other headlamp functions, such as complementary use in conjunction with side marker or turn signal lights, and/or activation of daytime running lights, may also be controlled.

### Examples

Example 1 is a high-power light emitting diode (LED) array comprising: an n-semiconductor layer and a p-semiconductor layer formed on a substrate, an active region between the n-semiconductor layer and p-semiconductor layer configured to emit light of the LED array; a mirror structure disposed on the n-semiconductor layer and the p-semiconductor layer and configured to reflect light from the active region back to the active region; dielectric layers on the mirror structure; an n-bonding layer and a p-bonding layer formed on the dielectric layers and respectively coupled to the n-semiconductor layer and p-semiconductor layer; and trenches that extend through an entirety of the n-semiconductor layer and the p-semiconductor layer to the substrate to form pixels, sidewalls of the trenches being substantially parallel with a growth direction of the n-semiconductor layer and the p-semiconductor layer.

In Example 2, the subject matter of Example 1 includes, wherein the substrate is patterned Sapphire.

In Example 3, the subject matter of Examples 1-2 includes, a Transparent Conductive Oxide (TCO) layer disposed between the p-semiconductor layer and the mirror structure; and a dielectric spacer disposed between the TCO layer and the mirror structure, the dielectric spacer comprising eVias that electrically couple the TCO layer and the mirror structure.

In Example 4, the subject matter of Example 3 includes, a hard mask spacer disposed on the mirror structure, the hard mask spacer comprising openings filled with a conductive material for current injection from the p-bonding layer to the mirror structure.

In Example 5, the subject matter of Example 4 includes, wherein the openings are uniformly distributed on one side of the hard mask spacer of each pixel.

In Example 6, the subject matter of Example 5 includes, wherein the openings are formed on alternating sides of the hard mask spacer of each pixel in each row of pixels.

In Example 7, the subject matter of Examples 1-6 includes, wherein a width of each of the trenches is at most about 5 microns.

In Example 8, the subject matter of Examples 1-7 includes, a multilayer dielectric spacer layer stack disposed on the sidewalls of the trenches, the dielectric spacer layer stack forming a photonic Bragg reflector.

In Example 9, the subject matter of Example 8 includes, wherein the multilayer dielectric spacer layer stack comprises a SiO2 layer and another dielectric layer formed from a material other than SiO2.

In Example 10, the subject matter of Examples 8-9 includes, wherein at least some layers of the multilayer dielectric spacer layer stack are disposed on at least one of the n-bonding layer and p-bonding layer, and at least other layers of the multilayer dielectric spacer layer stack are disposed between and the at least one of the n-bonding layer and p-bonding layer.

In Example 11, the subject matter of Examples 1-10 includes, nVias disposed in a center of each pixel to provide electrical contact to the n-semiconductor layer.

In Example 12, the subject matter of Examples 1-11 includes, wherein the pixels are coupled in series using the n-bonding layer and the p-bonding layer.

In Example 13, the subject matter of Example 12 includes, a redistribution dielectric layer disposed on the n-bonding layer and p-bonding layer, the redistribution dielectric layer having a first opening to the n-bonding layer of a first pixel of the pixels coupled in series and a second opening to the p-bonding layer of a last pixel of the pixels coupled in series.

In Example 14, the subject matter of Example 13 includes, an n-Under Bump Metallurgy (UBM) pad and a p-UBM pad deposited or otherwise formed on the redistribution dielectric layer, the n-UBM pad electrically coupled to the n-bonding layer of the first pixel via the first opening, the p-UBM pad electrically coupled to the p-bonding layer of the last pixel via the first opening.

In Example 15, the subject matter of Examples 1-14 includes, wherein the mirror structure is an Ag mirror.

Example 16 is a method of forming a high-power light emitting diode (LED) array, the method comprising: forming an n-semiconductor layer and a p-semiconductor layer on a substrate, an active region between the n-semiconductor layer and p-semiconductor layer configured to emit light of the LED array; forming a mirror structure on the n-semiconductor layer and p-semiconductor layer, the mirror structure configured to reflect light from the active region back to the active region; forming a hard mask spacer on the mirror structure; forming dielectric layers on the hard mask spacer; forming an n-bonding layer and a p-bonding layer on the dielectric layers, the n-and p-bonding layers respectively coupled to the n-and p-semiconductor layers; and etching trenches that extend substantially perpendicularly through an entirety of the n-semiconductor layer and the p-semiconductor layer to form pixels, sidewalls of the trenches being substantially parallel with a growth direction of the n-semiconductor layer and p-semiconductor layer.

In Example 17, the subject matter of Example 16 includes, forming a dielectric spacer on the p-semiconductor layer, the mirror structure formed on the dielectric spacer; and forming e Vias in the dielectric spacer.

In Example 18, the subject matter of Examples 16-17 includes, forming openings in the hard mask spacer and filling the openings with a conductive material for current injection from the p-bonding layer to the mirror structure.

In Example 19, the subject matter of Example 18 includes, wherein the openings are uniformly distributed on one side of the hard mask spacer of each pixel.

In Example 20, the subject matter of Example 19 includes, wherein the openings are formed on alternating sides of the hard mask spacer of each pixel in each row of pixels.

In Example 21, the subject matter of Examples 16-20 includes, forming a multilayer dielectric spacer layer stack on the sidewalls of the trenches, the dielectric spacer layer stack forming a photonic Bragg reflector.

In Example 22, the subject matter of Example 21 includes, wherein at least some layers of the multilayer dielectric spacer layer stack are disposed on at least one of the n-bonding layer and the p-bonding layer, and at least other layers of the multilayer dielectric spacer layer stack are disposed between and the at least one of the n-bonding layer and the p-bonding layer.

In Example 23, the subject matter of Examples 16-22 includes, forming nVias in a center of each pixel to contact the n-semiconductor layer.

In Example 24, the subject matter of Examples 16-23 includes, using the n-bonding layer and p-bonding layer to couple the pixels in series.

In Example 25, the subject matter of Example 24 includes, forming a redistribution dielectric layer on the n-bonding layer and p-bonding layer; and forming, in the redistribution dielectric layer, a first opening to the n-bonding layer of a first pixel of the pixels coupled in series and a second opening to the p-bonding layer of a last pixel of the pixels coupled in series.

In Example 26, the subject matter of Example 25 includes, forming an n-Under Bump Metallurgy (UBM) pad and a p-UBM pad on the redistribution dielectric layer, the n-UBM pad electrically coupled to the n-bonding layer of the first pixel via the first opening, the p-UBM pad electrically coupled to the p-bonding layer of the last pixel via the first opening.

Example 27 is a vehicle headlamp comprising: a high-power light emitting diode (LED) array that comprises: the n-semiconductor layer and the p-semiconductor layer formed on a substrate, an active region between the n-semiconductor layer and the p-semiconductor layer configured to emit light of the LED array; a mirror structure disposed on the n-semiconductor layer and the p-semiconductor layer and configured to reflect light from the active region back to the active region; dielectric layers on the mirror structure; an n-bonding layer and a p-bonding layer formed on the dielectric layers and respectively coupled to the n-semiconductor layer and the p-semiconductor layer; and trenches that extend through an entirety of the n-semiconductor layer and the p-semiconductor layer to the substrate to form pixels, sidewalls of the trenches being substantially parallel with a growth direction of the n-semiconductor layer and the p-semiconductor layer; and a driver configured to drive the high-power LED array at voltages greater than about 6V.

In Example 28, the subject matter of Example 27 includes, a Transparent Conductive Oxide (TCO) layer disposed between the p-semiconductor layer and the mirror structure; and a dielectric spacer disposed between the TCO layer and the mirror structure, the dielectric spacer comprising eVias that electrically couple the TCO layer and the mirror structure.

In Example 29, the subject matter of Example 28 includes, a hard mask spacer disposed on the mirror structure, the hard mask spacer comprising openings filled with a conductive material for current injection from the p-bonding layer to the mirror structure.

In Example 30, the subject matter of Examples 27-29 includes, a multilayer dielectric spacer layer stack disposed on the sidewalls of the trenches, the dielectric spacer layer stack forming a photonic Bragg reflector.

In Example 31, the subject matter of Example 30 includes, wherein at least some layers of the multilayer dielectric spacer layer stack are disposed on at least one of the n-bonding layer and the p-bonding layer, and at least other layers of the multilayer dielectric spacer layer stack are disposed between and the at least one of the n-bonding layer and the p-bonding layer.

In Example 32, the subject matter of Examples 27-31 includes, nVias disposed in a center of each pixel to provide electrical contact to the n-semiconductor layer.

In Example 33, the subject matter of Examples 27-32 includes, wherein the pixels are coupled in series using the n-bonding layer and the p-bonding layer.

In Example 34, the subject matter of Example 33 includes, a redistribution dielectric layer disposed on the n-bonding layer and the p-bonding layer, the redistribution dielectric layer having a first opening to the n-bonding layer of a first pixel of the pixels coupled in series and a second opening to the p-bonding layer of a last pixel of the pixels coupled in series.

In Example 35, the subject matter of Example 34 includes, an n-Under Bump Metallurgy (UBM) pad and a p-UBM pad formed on the redistribution dielectric layer, the n-UBM pad electrically coupled to the n-bonding layer of the first pixel via the first opening, the p-UBM pad electrically coupled to the p-bonding layer of the last pixel via the first opening.

Example 36 is at least one machine-readable medium including instructions that, when executed by processing circuitry, cause the processing circuitry to perform operations to implement of any of Examples 1-35.

Example 37 is an apparatus comprising means to implement of any of Examples 1-35.

Example 38 is a system to implement of any of Examples 1-35.

Example 39 is a method to implement of any of Examples 1-35.

Although an embodiment has been described with reference to specific example embodiments, it will be evident that various modifications and changes may be made to these embodiments without departing from the broader scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The subject matter may be referred to herein, individually and/or collectively, by the term “embodiment” merely for convenience and without intending to voluntarily limit the scope of this application to any single inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, UE, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. For example, the term “a processor” configured to carry out specific operations includes both a single processor configured to carry out all of the operations as well as multiple processors individually configured to carry out some or all of the operations (which may overlap) such that the combination of processors carry out all of the operations.

The Abstract of the Disclosure is submitted with the understanding that it will not be used to interpret or limit the scope or meaning of the claims. In addition, in the foregoing Detailed Description, it may be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

1. A high-power light emitting diode (LED) array comprising:
an n-semiconductor layer and a p-semiconductor layer formed on a substrate, an active region between the n-semiconductor layer and p-semiconductor layer configured to emit light of the LED array;
a mirror structure disposed on the n-semiconductor layer and the p-semiconductor layer, the mirror structure configured to reflect light from the active region back to the active region;
dielectric layers disposed on the mirror structure;
an n-bonding layer and a p-bonding layer disposed on the dielectric layers and respectively coupled to the n-semiconductor layer and p-semiconductor layer; and
trenches that extend through an entirety of the n-semiconductor layer and the p-semiconductor layer to the substrate to form pixels, sidewalls of the trenches being substantially parallel with a growth direction of the n-semiconductor layer and the p-semiconductor layer,
wherein the pixels are coupled in series from a first pixel to a last pixel by connecting the p-bonding layer of each pixel to the n-bonding layer of an adjacent pixel, the bonding layers extending over the trenches between adjacent pixels, and
wherein a redistribution dielectric layer is disposed on the n-bonding layer and the p-bonding layer, the redistribution dielectric layer limited to two openings that include a first opening to the n-bonding layer of the first pixel and a second opening to the p-bonding layer of the last pixel.

2. The high-power LED array of claim 1, further comprising:
a Transparent Conductive Oxide (TCO) layer disposed between the p-semiconductor layer and the mirror structure; and
a dielectric spacer disposed between the TCO layer and the mirror structure, the dielectric spacer comprising e Vias that electrically couple the TCO layer and the mirror structure.

3. The high-power LED array of claim 2, further comprising a hard mask spacer disposed on the mirror structure, the hard mask spacer comprising openings filled with a conductive material for current injection from the p-bonding layer to the mirror structure.

4. The high-power LED array of claim 3, wherein the openings are uniformly distributed on one side of the hard mask spacer of each pixel.

5. The high-power LED array of claim 4, wherein the openings are formed on alternating sides of the hard mask spacer of each pixel in each row of pixels.

6. The high-power LED array of claim 1, further comprising a multilayer dielectric spacer layer stack disposed on the sidewalls of the trenches, the dielectric spacer layer stack forming a photonic Bragg reflector.

7. The high-power LED array of claim 6, wherein at least some layers of the multilayer dielectric spacer layer stack are disposed on at least one of the n-bonding layer and p-bonding layer, and at least other layers of the multilayer dielectric spacer layer stack are disposed between and the at least one of the n-bonding layer and p-bonding layer.

8. The high-power LED array of claim 1, further comprising nVias disposed in a center of each pixel to provide electrical contact to the n-semiconductor layer.

9. The high-power LED array of claim 1, wherein the pixels are coupled in series using the n-bonding layer and the p-bonding layer.

10. The high-power LED array of claim 9, further comprising a redistribution dielectric layer disposed on the n-bonding layer and p-bonding layer, the redistribution dielectric layer having a first opening to the n-bonding layer of a first pixel of the pixels coupled in series and a second opening to the p-bonding layer of a last pixel of the pixels coupled in series.

11. The high-power LED array of claim 10, further comprising an n-Under Bump Metallurgy (UBM) pad and a p-UBM pad deposited or otherwise formed on the redistribution dielectric layer, the n-UBM pad electrically coupled to the n-bonding layer of the first pixel via the first opening, the p-UBM pad electrically coupled to the p-bonding layer of the last pixel via the first opening.

12. The high-power LED array of claim 1, wherein:
a width of each of the trenches is at most about 5 microns,
the mirror structure is an Ag mirror, and
the substrate is patterned Sapphire.

13. A method of forming a high-power light emitting diode (LED) array, the method comprising:
forming an n-semiconductor layer and a p-semiconductor layer on a substrate, an active region between the n-semiconductor layer and p-semiconductor layer configured to emit light of the LED array;
forming a mirror structure on the n-semiconductor layer and p-semiconductor layer, the mirror structure configured to reflect light from the active region back to the active region;
forming a hard mask spacer on the mirror structure;
forming dielectric layers on the hard mask spacer;
forming an n-bonding layer and a p-bonding layer on the dielectric layers, the n-bonding layer and the p-bonding layer respectively coupled to the n-semiconductor layer and the p-semiconductor layer; and
etching trenches that extend substantially perpendicularly through an entirety of the n-semiconductor layer and the p-semiconductor layer to form pixels, sidewalls of the trenches being substantially parallel with a growth direction of the n-semiconductor layer and p-semiconductor layer,
wherein the pixels are coupled in series from a first pixel to a last pixel by connecting the p-bonding layer of each pixel to the n-bonding layer of an adjacent pixel, the bonding layers extending over the trenches between adjacent pixels, and
wherein a redistribution dielectric layer is disposed on the n-bonding layer and the p-bonding layer, the redistribution dielectric layer limited to two openings that include a first opening to the n-bonding layer of the first pixel and a second opening to the p-bonding layer of the last pixel.

14. The method of claim 13, further comprising:
forming a dielectric spacer on the p-semiconductor layer, the mirror structure formed on the dielectric spacer;
forming e Vias in the dielectric spacer; and
forming openings in the hard mask spacer and filling the openings with a conductive material for current injection from the p-bonding layer to the mirror structure.

15. The method of claim 13, further comprising forming a multilayer dielectric spacer layer stack on the sidewalls of the trenches, the dielectric spacer layer stack forming a photonic Bragg reflector, wherein:
at least some layers of the multilayer dielectric spacer layer stack are disposed on at least one of the n-bonding layer and the p-bonding layer, and
at least other layers of the multilayer dielectric spacer layer stack are disposed between and the at least one of the n-bonding layer and the p-bonding layer.

16. The method of claim 13, further comprising:
using the n-bonding layer and p-bonding layer to couple the pixels in series;
forming a redistribution dielectric layer on the n-bonding layer and p-bonding layer;
forming, in the redistribution dielectric layer, a first opening to the n-bonding layer of a first pixel of the pixels coupled in series and a second opening to the p-bonding layer of a last pixel of the pixels coupled in series; and
forming an n-Under Bump Metallurgy (UBM) pad and a p-UBM pad on the redistribution dielectric layer, the n-UBM pad electrically coupled to the n-bonding layer of the first pixel via the first opening, the p-UBM pad electrically coupled to the p-bonding layer of the last pixel via the first opening.

17. A vehicle headlamp comprising:
a high-power light emitting diode (LED) array that comprises:
an n-semiconductor layer and a p-semiconductor layer formed on a substrate, and an active region between the n-semiconductor layer and the p-semiconductor layer configured to emit light of the LED array;
a mirror structure disposed on the n-semiconductor layer and the p-semiconductor layer and configured to reflect light from the active region back to the active region;
dielectric layers on the mirror structure;
an n-bonding layer and a p-bonding layer formed on the dielectric layers and respectively coupled to the n-semiconductor layer and the p-semiconductor layer; and
trenches that extend through an entirety of the n-semiconductor layer and the p-semiconductor layer to the substrate to form pixels, sidewalls of the trenches being substantially parallel with a growth direction of the n-semiconductor layer and the p-semiconductor layer; and
a driver configured to drive the high-power LED array at voltages greater than about 6V.
wherein the pixels are coupled in series from a first pixel to a last pixel by connecting the p-bonding layer of each pixel to the n-bonding layer of an adjacent pixel, the bonding layers extending over the trenches between adjacent pixels, and
wherein a redistribution dielectric layer is disposed on the n-bonding layer and the p-bonding layer, the redistribution dielectric layer limited to two openings that include a first opening to the n-bonding layer of the first pixel and a second opening to the p-bonding layer of the last pixel.

18. The vehicle headlamp of claim 17, further comprising:
a Transparent Conductive Oxide (TCO) layer disposed between the p-semiconductor layer and the mirror structure;
a dielectric spacer disposed between the TCO layer and the mirror structure, the dielectric spacer comprising e Vias that electrically couple the TCO layer and the mirror structure; and
a hard mask spacer disposed on the mirror structure, the hard mask spacer comprising openings filled with a conductive material for current injection from the p-bonding layer to the mirror structure.

19. The vehicle headlamp of claim 17, further comprising a multilayer dielectric spacer layer stack disposed on the sidewalls of the trenches, the dielectric spacer layer stack forming a photonic Bragg reflector, wherein at least some layers of the multilayer dielectric spacer layer stack are disposed on at least one of the n-bonding layer and the p-bonding layer, and at least other layers of the multilayer dielectric spacer layer stack are disposed between and the at least one of the n-bonding layer and the p-bonding layer.

20. The vehicle headlamp of claim 17, further comprising:
nVias disposed in a center of each pixel to provide electrical contact to the n-semiconductor layer, the pixels coupled in series using the n-bonding layer and the p-bonding layer;
a redistribution dielectric layer disposed on the n-bonding layer and the p-bonding layer, the redistribution dielectric layer having a first opening to the n-bonding layer of a first pixel of the pixels coupled in series and a second opening to the p-bonding layer of a last pixel of the pixels coupled in series; and
an n-Under Bump Metallurgy (UBM) pad and a p-UBM pad formed on the redistribution dielectric layer, the n-UBM pad electrically coupled to the n-bonding layer of the first pixel via the first opening, the p-UBM pad electrically coupled to the p-bonding layer of the last pixel via the first opening.
